(19) United States
(12) Patent Application Publication
(10) Pub. No.: US 2012/0167939 A1
(43) Pub. Date: Jul. 5, 2012

(54) DEVICE ARCHITECTURE FOR DYE SENSITIZED SOLAR CELLS AND PHOTOELECTROCHEMICAL CELLS AND MODULES

(75) Inventor: BAL MUKUND DHAR, Gaithersburg, MD (US)

(73) Assignee: AGIRA INC., Baltimore, MD (US)

(21) Appl. No.: 13/341,104

(22) Filed: Dec. 30, 2011

Related U.S. Application Data
(60) Provisional application No. 61/429,388, filed on Jan. 3, 2011.

(51) Int. Cl. H01L 31/042; H01L 31/02

(52) U.S. Cl. 136/244; 136/255

(57) ABSTRACT

Dye Sensitized Solar Cells (DSSCs) and Photoelectrochemical Cells (PECs) have shown great progress toward conversion of light to electricity and chemical fuels in past. However, the presence of liquid electrolytes poses challenges in integration of large area modules, difficulty in implementing tandem architectures and sealing issues which lead to lower lifetimes of the modules. This invention addresses these issues by means of a novel design consisting of multiple nested concentric tubes leading to multi-cell tandem architecture of DSSCs and PECs. Each tube of this design comprises an electrode. At least one of the electrodes in this design is responsive to light and carries electronic charge (electrons or holes). The space between the tubes is filled with an electrolyte carrying ionic charge and participating in redox processes with the electrodes. This design facilitates higher efficiency, better lifetimes and a facile method of integration of large area modules.

### CROSS-REFERENCE TO RELATED APPLICATIONS

This application claims benefit of priority to U.S. Provisional Patent Application No. 61/429,388 to Dhar, entitled “New Design and Device Architecture for Dye Sensitized Solar Cells and Photoelectrochemical Cells and Modules,” filed Jan. 3, 2011 which is incorporated herein by reference in its entirety.

### BACKGROUND

1. Field of the Invention

The present invention relates to solar cells and photoelectrochemical cells.

2. Related Art

Existing solar cells and photoelectrochemical cells are not very efficient and are subject to leakage and environmental damage.

### SUMMARY

According to a first broad aspect, the present invention provides a device comprising one or more nested concentric tube modules, each nested concentric tube module comprising: an outer tube having first coating layers coated on a inner side thereof, and an inner tube having second coating layers coated on an outer side thereof, wherein the inner tube is mounted inside the outer tube, is concentric with the outer tube and is spaced from the outer tube, wherein the first coating layers comprise: a first transparent conductor layer, a porous semiconductor layer on the first transparent conductor layer and an absorbing layer on the porous semiconductor layer, wherein the second coating layers comprise a second transparent conductor layer and an interfacial conductor layer on the second transparent conductor layer, and wherein the porous semiconductor layer comprises one or more porous n-type semiconductor materials with pores having a diameter of about 2 nm to 1 nm.

According to a second broad aspect, the present invention provides a device comprising one or more nested concentric tube modules, each nested concentric tube module comprising: an outer tube having first coating layers coated on a inner side thereof, and an inner tube having second coating layers coated on an outer side thereof, wherein the inner tube is mounted inside the outer tube, is concentric with the outer tube and is spaced from the outer tube, wherein the first coating layers comprise a first transparent conductor layer and an interfacial conductor layer on the first transparent conductor layer, wherein the second coating layers comprise: a second transparent conductor layer, a porous semiconductor layer on the second transparent conductor layer and an absorbing layer on the porous semiconductor layer, and wherein the porous semiconductor layer comprises one or more porous n-type semiconductor materials with pores having a diameter of about 2 nm to 1 μm.

According to a third broad aspect, the present invention provides a device comprising one or more nested concentric tube modules, each nested concentric tube module comprising: an outer tube having first coating layers coated on a inner side thereof, and an inner tube having second coating layers coated on an outer side thereof, wherein the inner tube is mounted inside the outer tube, is concentric with the outer tube and is spaced from the outer tube, wherein the first coating layers comprise: a first transparent conductor layer, a first porous semiconductor layer on the first transparent conductor layer and a first absorbing layer on the first porous semiconductor layer, wherein the second coating layers comprise: a second transparent conductor layer and a second porous semiconductor layer on the second transparent conductor layer, wherein the first porous semiconductor layer comprises one or more porous n-type semiconductor materials with pores having a diameter of about 2 nm to 1 μm, and wherein the second porous semiconductor layer comprises one or more porous p-type semiconductor materials with pores having a diameter of about 2 nm to 1 μm.

According to a fourth broad aspect, the present invention provides a device comprising one or more nested concentric tube modules, each nested concentric tube module comprising: an outer tube having first coating layers coated on a inner side thereof, and an inner tube having second coating layers coated on an outer side thereof, wherein the inner tube is mounted inside the outer tube, is concentric with the outer tube and is spaced from the outer tube, wherein the first coating layers comprise: a first transparent conductor layer and a first porous semiconductor layer on the first transparent conductor layer, wherein the second coating layers comprise: a second transparent conductor layer, a second porous semiconductor layer on the second transparent conductor layer and a first absorbing layer on the first porous semiconductor layer, wherein the first porous semiconductor layer comprises one or more porous p-type semiconductor materials with pores having a diameter of about 2 nm to 1 μm, and wherein the second porous semiconductor layer comprises one or more porous n-type semiconductor materials with pores having a diameter of about 2 nm to 1 μm.

According to a fifth broad aspect, the present invention provides a device comprising one or more nested concentric tube modules, each nested concentric tube module comprising: an outer tube having first coating layers coated on a inner side thereof, and an inner tube having second coating layers coated on an outer side thereof, wherein the inner tube is mounted inside the outer tube, is concentric with the outer tube and is spaced from the outer tube, wherein the first coating layers comprise: a first transparent conductor layer, a first porous semiconductor layer on the first transparent conductor layer and a first absorbing layer on the first porous semiconductor layer, wherein the second coating layers comprise: a second transparent conductor layer, a second porous semiconductor layer on the second transparent conductor layer and a second absorbing layer on the second porous semiconductor layer, wherein the first porous semiconductor layer comprises one or more porous n-type semiconductor materials with pores having a diameter of about 2 nm to 1 μm, and wherein the second porous semiconductor layer comprises one or more porous n-type semiconductor materials with pores having a diameter of about 2 nm to 1 μm.

According to a sixth broad aspect, the present invention provides a device comprising one or more nested concentric tube modules, each nested concentric tube module comprising: an outer tube having first coating layers coated on a inner side thereof, and an inner tube having second coating layers coated on an outer side thereof, wherein the inner tube is mounted inside the outer tube, is concentric with the outer tube and is spaced from the outer tube, wherein the first coating layers comprise: a first transparent conductor layer and a first porous semiconductor layer on the first transparent conductor layer, wherein the second coating layers comprise: a second transparent conductor layer and a second porous semiconductor layer on the second transparent conductor layer, wherein the first porous semiconductor layer comprises one or more porous p-type semiconductor materials with pores having a diameter of about 2 nm to 1 μm, and wherein the second porous semiconductor layer comprises one or more porous p-type semiconductor materials with pores having a diameter of about 2 nm to 1 μm.

### BRIEF DESCRIPTION OF THE DRAWINGS

The accompanying drawings, which are incorporated herein and constitute part of this specification, illustrate exemplary embodiments of the invention, and, together with the general description given above and the detailed description given below, serve to explain the features of the invention. The accompanying drawings are primarily designed for ease of illustration and, therefore, various parts of these drawings are not drawn to scale.

FIG. 1 is a schematic diagram of a dye sensitized solar cell (DSSC).

FIG. 2 is a schematic diagram showing the operation of a DSSC.

FIG. 3 is a schematic cross-sectional view of an inner tube and an outer tube of a nested concentric tube module according to one embodiment of the present invention.

FIG. 4 is a schematic cross-sectional view of a concentric tube solar cell according to one embodiment of the present invention.

FIG. 5 is a schematic cross-sectional view of an inner tube, a middle tube and an outer tube of a nested concentric tube module according to one embodiment of the present invention.

FIG. 6 is a schematic cross-sectional view of a concentric tube solar cell according to one embodiment of the present invention.

FIG. 7 is a perspective view of a coating pattern on a tube according to one embodiment of the present invention.

FIG. 8 is a perspective view of spacer according to one embodiment of the present invention.

FIG. 9 is a schematic cross-sectional view of a concentric tube solar cell with a cell cap according to one embodiment of the present invention.

FIG. 10 is a bottom view of the cell cap of FIG. 9.

FIG. 11 is a schematic cross-sectional view of a concentric tube solar cell with a cell cap according to one embodiment of the present invention.

FIG. 12 is a schematic cross-sectional view of a sealed concentric tube solar cell according to one embodiment of the present invention.

FIG. 13 is a schematic cross-sectional view of a sealed concentric tube solar cell according to one embodiment of the present invention.

FIG. 14 is a schematic cross-sectional view of a concentric tube solar cell with an ion exchange membrane according to one embodiment of the present invention.

FIG. 15 is a schematic cross-sectional view of a nested concentric tube module composed of tapered tubes according to one embodiment of the present invention.

FIG. 16 is a perspective view of a circular lampshade-shaped module according to one embodiment of the present invention.

FIG. 17 is a perspective view of a solar tower comprising four circular lampshade-shaped modules according to one embodiment of the present invention.

FIG. 18 is a perspective view of an array of solar towers according to one embodiment of the present invention.

FIG. 19 is a perspective view of a two-row rectangular module according to one embodiment of the present invention.

FIG. 20 is perspective view a four-row rectangular module according to one embodiment of the present invention.

### DETAILED DESCRIPTION OF THE PREFERRED EMBODIMENTS

### Definitions

Where the definition of terms departs from the commonly used meaning of such terms, this description utilizes the definitions provided below, unless specifically indicated.

For purposes of the present invention, it should be noted that the singular forms, “a,” “an,” and “the” include reference to the plural unless the context as herein presented clearly indicates otherwise.

For purposes of the present invention, directional terms such as “top,” “bottom,” “upper,” “lower,” “above,” “below,” “left,” “right,” “horizontal,” “vertical,” “up,” “down,” etc. are merely used for convenience in describing the various embodiments of the present invention. The embodiments of the present invention may be oriented in various ways. For example, the diagrams, apparatuses, etc. shown in the drawing figures may be flipped over, rotated by 90° in any direction, reversed, etc.

For purposes of the present invention, the term “absorbing layer” refers to a layer comprising one or more light absorbing materials. Examples of light absorbing materials include dyes such as Ruthenium based dyes, indoline dyes, phthalocynanine dyes etc. Other examples of light absorbing materials include semiconductor nanoparticles or semiconductor nanocrystals (quantum dots) such as cadmium selenide, cadmium sulfide, cadmium telluride, lead sulfide, lead selenide, copper sulfide, indium arsenide, indium phosphide, etc. and various others.

For purposes of the present invention, the term “interfacial conductor layer” refers to a layer comprising one or more conducting materials for participation in the a redox reaction with an electrolyte. A interfacial conductor layer provides a least resistance pathway for charged carriers to move to a transparent conductor layer below the interfacial conductor layer.

For purposes of the present invention, the term “dye layer” refers to a layer comprising one or more types of dye molecules. Other materials may or may not be present in this layer. A dye layer is one type of absorbing layer.

For purposes of the present invention, the term “electrolyte” refers to the conventional meaning of the term “electrolyte,” i.e., a material containing free ions that make the material electrically conductive by the motion of free ions under the influence of external or internal electric fields. A electrolyte may be in various forms such as a liquid, a gel, a solid, etc. In one embodiment the electrolyte is a liquid, such as an ionic solution with a salt dissolved in a solvent. In one embodiment, an electrolyte may be a liquid or gel that is used to at least partially fill the space between two tubes and is then can be transformed into a solid electrolyte. For example, a solid electrolyte may be formed by exposing an electrolyte that is a liquid or gel to light and/or heat. In one embodiment of the present invention, the electrolyte may be an ionic liquid.

For purposes of the present invention, the term “extend through,” when referring to the mounting of a module on a post or other type of member, unless specified otherwise, also includes extending through and to the edge of the module. For example, although the post extends through and past the edge of the smaller circular member of each of the modules of FIG. 17, in some embodiments of the present invention a post may “extend through” just to an edge of a circular module.

For purposes of the present invention, the term “fluorinated tin oxide (FTO) layer” refers to a layer comprising FTO.

For purposes of the present invention, the term “light” refers to the entire electromagnetic spectrum including visible light, ultraviolet light, infrared light, gamma rays, x-rays, etc.

For purposes of the present invention, the term “mesoporous oxide” refers to oxides that are “mesoporous,” i.e., have a pore size of 2 to 50 nm. Examples of suitable mesoporous oxides that may be used in embodiments of the present invention include TiO₂, ZnO, SnO₂, WO₃, Fe₂O₃ etc.

For purposes of the present invention, the term “mesoporous layer” refers to a layer comprising one or more mesoporous materials such as one or more mesoporous oxides.

For purposes of the present invention, the term “mesoporous semiconductor layer” refers to a mesoporous layer that is comprises of one or more semiconductor materials such as n-type semiconductors such as TiO₂, ZnO, SnO₂ or p-type semiconductors NiO and CuO. A mesoporous semiconductor layer is one example of a porous material layer of the present invention in which the porous material of the porous material layer has pores with a diameter of about 2 nm to 1 μm.

For purposes of the present invention, the term “neighboring” refers to the tube closest to another tube. For example, in a pair of nested tubes comprising an outer tube and an inner tube, the outer tube and inner tube are neighboring tubes with respect to each other. For the case where there are three nested tubes comprising an inner tube, a middle tube and an outer tube, the middle tube is a neighboring tube to the inner tube and the middle tube is also a neighboring tube to the outer tube.

For purpose of the present invention the term “photoelectrochemical cell (PEC)” refers to the conventional meaning of this term, i.e., an electrochemical cell comprising two electrodes, i.e., an anode and a cathode, separated by an electrolyte where one or both of the electrodes are responsive to light. Examples of combination of electrodes in a PEC include: a photoanode and cathode, an anode and a photocathode, and a photoanode and photocathode. In one example of a series tandem device, the photoanode and photocathode coupled together. A typical photoanode consists of a layer of a light absorbing material (dye) stacked on top of an electron transporting material (n type), such as TiO₂ and transparent conductive electrode. The dye absorbs light and transfers electron to electron transporting material which is taken to external circuit. The hole left behind on the dye participates in a reduction reaction with the electrolyte. The charged ionic species so generated migrates to the cathode (platinum or carbon) and participates in an oxidation reaction thereby giving a hole to the cathode which is taken to the external circuit.

For purposes of the present invention the term “photovoltaic device” refers to the conventional meaning of this term, i.e., a device comprising two layers of the same material with different dopant impurities (or two different materials) that are stacked on top of each other. This constitutes a p-n junction (or a heterojunction). One or both of these materials participate in absorption of light and/or charge separation and/or charge transport. The electrons and holes so generated are collected respectively at the anode and cathode (conducting electrodes) and thus contribute to current and voltage in external circuit. The anode and cathode may be a metal or a transparent conducting layer or a highly doped semiconductor that is stacked on either side of the p-n junction.

For purposes of the present invention, the term “porous semiconductor layer” refers to a layer that comprises one or more semiconductors and that is porous. In one embodiment, the porous semiconductor layer has pores that have a pore size of 2 nm to 1 μm. A porous semiconductor layer may be a mesoporous layer. A porous semiconductor layer may also be a nanocrystalline semiconducting film comprising nanoparticles, nanowires, nanotubes, nanocones, etc. For purpose of this invention, the porous semiconductor layer may have a thickness in the range of 0.2 μm to 20 μm.

For purposes of the present invention, the term “solar spectrum” refers to the portion of the electromagnetic spectrum emitted by the sun.

For purposes of the present invention, a “tapered tube” refers to a tube in which a portion of the tube is tapered. An advantage of using one or more tapered tubes in the cells of the present invention is that the distance between neighboring tubes is not determined solely by the diameter of either tube by how far one tapered tube is inserted within a neighboring tapered tube.

For purposes of the present invention, the term “transparent conductor” refers to a transparent or nearly transparent material that is a conductor of electricity. Examples of suitable transparent conductors that may be used in embodiments of the present invention include Fluorine doped Tin Oxide (FTO), Tin-doped Indium oxide (ITO), Fluorine doped Zinc Oxide (FZO), Aluminum doped Zinc Oxide (AZO) etc.

For purposes of the present invention, the term “transparent conductor layer” refers to a layer comprising one or more transparent conductors. Other materials may or may not be present in this layer.

For purposes of the present invention, the term “tube” refers to any type of tube whether open or closed-end, unless specified otherwise. Examples of closed-end tubes include test tubes, centrifuge tubes, etc. Although shown as having a test tube shape in the embodiments of the present invention shown in the drawings, the tubes of the present invention may have various shapes. The tubes of the present invention may also have various lengths, various diameters, various cross-section shapes, etc. The walls of the tubes may be may have various diameters along the length of the tube.

### DESCRIPTION

Dye sensitized solar cells (DSSCs) have been around for almost two decades as a promising photovoltaic technology for mass scale adoption with least environmental impact. However there have been certain key issues that have been bottlenecks to using DSSCs. One important issue is that the efficiencies of DSSCs have not gone beyond 12% for lab cells as opposed to approximately 19% for copper indium gallium selenide (CIGS) based lab cells and >20% for mono-crystalline silicon based lab cells. Various tandem architectures to increase the efficiencies have been proposed but their integration into modules presents engineering challenges in fabrication and sealing particularly because of the liquid electrolyte. A significant research effort has been focused on developing solid state DSSCs, but the efficiencies of solid state DSSCs are quite low. The lifetimes have not been able to match that of silicon based solar cells. One of the major reasons that DSSCs with liquid or gel electrolyte have lower lifetimes is that improper encapsulation of the DSSC modules can lead to degradation from environmental factors. Therefore, there are ongoing challenges in fabrication and sealing of large area DSSC modules.

In one embodiment, the present invention provides a photoelectrochemical cell. In one embodiment of the present invention, the photoelectrochemical cell may be a dye sensitized solar cell (DSSC).

In one embodiment, the present invention provides a nested concentric tube module device comprising two concentric cylindrical electrodes (one being photoanode and other being cathode) and the space between them being filled with an electrolyte. Each tube carries the electronic charge (of different polarity) and the electrolyte in between carries the ionic charge and participates in a redox reaction with the two electrodes.

In one embodiment, the present invention provides a nested concentric tube module device comprising three or more concentric tubes.

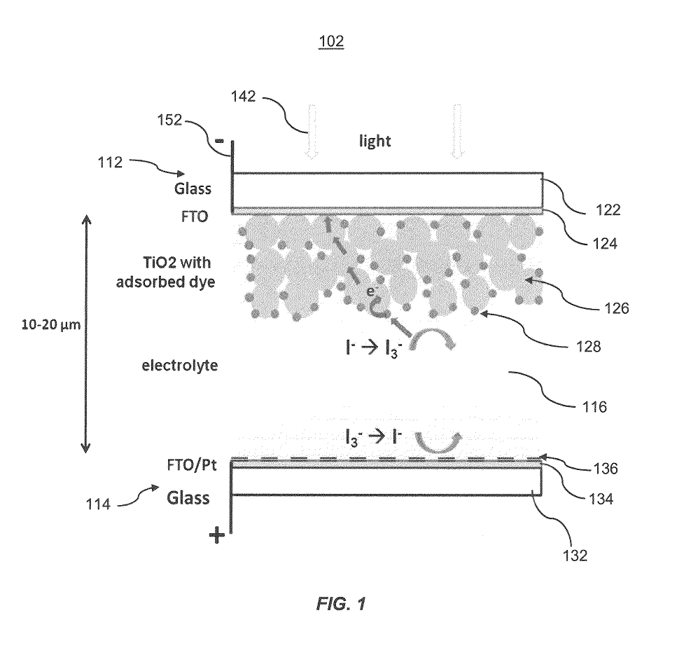

The first photoelectrochemical cells for water splitting to produce H₂ gas as a fuel were reported in 1972 by Honda and Fujishima [1] and used a TiO₂ electrode for the purpose. DSSCs were invented by O'Regan and Gratzel [2] in 1991 to convert light absorbed by a dye adsorbed on a TiO₂ surface into charge carriers that can then be collected at the two electrodes of the cell. DSSCs are usually made on flat substrates as shown in FIG. 1.

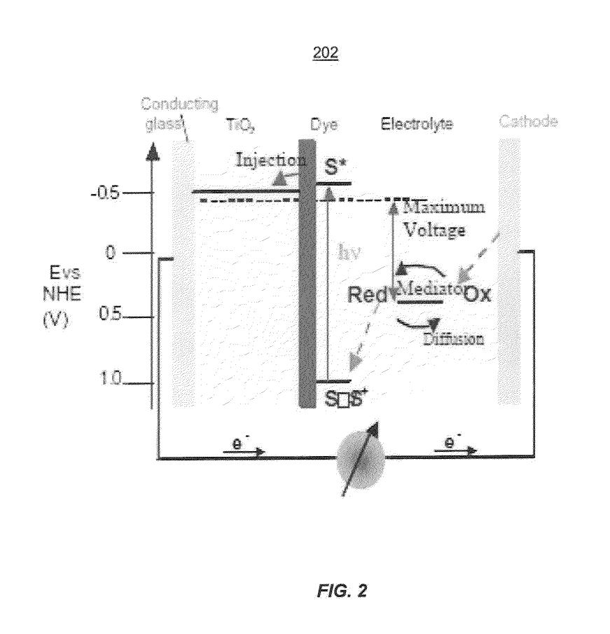

FIG. 1 shows a DSSC 102 having a photoanode 112 and a cathode 114 with electrolyte 116 sandwiched between photoanode 112 and cathode 114. Photoanode 112 comprises a layer of glass 122 coated with an FTO layer 124 comprising transparent and conductive fluorine-doped tin oxide (FTO), a layer of TiO₂ nanoparticles 126 (large circles) and dye molecules 128 (small circles) adsorbed on surfaces of TiO₂ nanoparticles 126. Cathode 114 has a layer of glass 132 that is coated with an FTO layer 134 and an electrical conductor layer 136 (shown as a dashed line) comprising platinum or carbon. In some literature reports carbon nanotubes, graphene and poly(3,4-ethylenedioxythiophene) poly(styrenesulfonate) (PEDOT:PSS) conducting polymer electrodes and their combinations have also been used. When light 142 shines on DSSC 102, photo-excited electron and hole pairs are produced as a result absorption of light 142. The electrons are transferred by dye molecules 128 to the layer of TiO₂ nanoparticles 126 and then to FTO layer 124 which carries the electrons to an external circuit 152. The holes which are left behind on dye molecules 128 are collected by electrolyte 116 via a reduction reaction at the photoanode. The oxidized ionic species in the electrolyte 116 migrates to the cathode 114 and participates in an oxidation reaction, gets reduced to its original state and transfers the hole to the cathode 114. The hole so collected is transported to the external circuit. The energy level diagram in FIG. 2 shows the mechanism of photo excitation and transport of charge in a DSSC.

FIG. 2 shows the operation of a DSSC 202 as shown in Gratzel [3]. Photo-excitation of sensitize (S) is followed by electron injection into the conduction band of mesoporous oxide semiconductor. The dye molecule is regenerated by the redox system, which itself is regenerated at the cathode (labeled “Cathode” in FIG. 2) by electrons passed through the load. Potentials are referred to versus the normal hydrogen electrode (NHE). The open circuit voltage of the solar cell corresponds to the difference between the redox potential of the mediator and the Fermi level of the nanocrystalline film indicated with a dashed line.

A review by Hagfeldt et al [4] discusses various scientific aspects and state of technology of the DSSCs and is incorporated herein by reference.

In one embodiment, the present invention provides a new design and device architecture of DSSCs and photoelectrochemical cell by employing tubes instead of the conventional flat surfaces currently used DSSCs and photoelectrochemical cells. The use of concentric tubes nested into each other tubes in various embodiments of the present invention also allows for large surface areas for chemical interactions to be produced for a given volume of electrolyte.

In one embodiment, the present invention provides DSSCs having a concentric tubular architecture employing tubes that are open at one or both ends. The tubes employed in a particular device of the present invention are chosen so that the tubes fit into each other in a nested arrangement. The tubes may be made of any insulating material such as glass, plastic, other transparent substrates, etc.

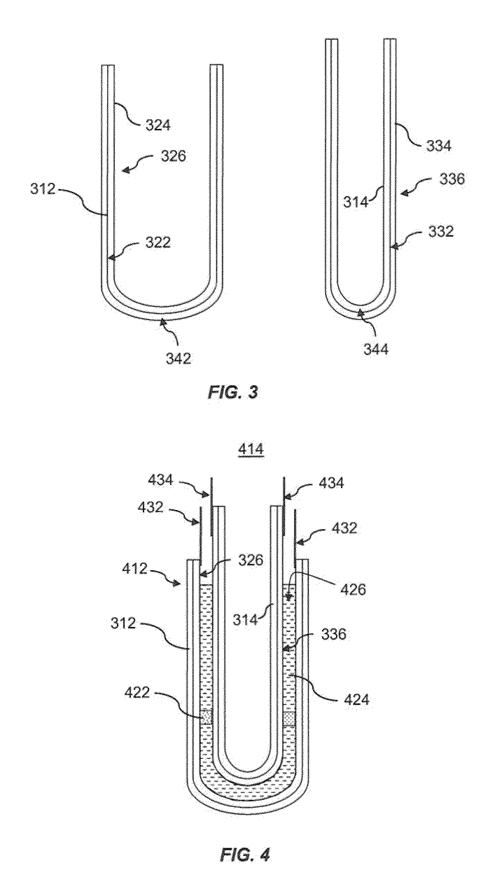

FIG. 3 shows an outer tube 312 in which may be nested in an inner tube 314 to form a nested concentric tube module of the present invention as shown in FIG. 4. Outer tube 312 has coated on an inner side 322 coating layers 324 to form an outer electrode 326 comprising outer tube 312 and coating layers 324. Inner tube 314 has coated on an outer side 332 coating layers 334 to form an inner electrode 336 comprising inner tube 314 and coating layers 334. Outer tube 312 has a closed end 342. Inner tube has a closed end 344.

FIG. 4 shows inner tube 314 mounted in outer tube 312 to form a nested concentric tube module 412 that is part of a DSSC 414. Inner tube 314 is spaced from outer tube 312 and held in place relative to outer tube 312 by an annular ring-shaped spacer 422. An electrolyte 424 partially fills a space 426 between outer tube 312 and inner tube 314. Electrical leads 432 electrically connect outer electrode 326 to other circuitry (not shown) that lead to battery, power inverter or DC load. Electrical leads 434 electrically connect inner electrode 336 to other circuitry (not shown) that lead to battery, power inverter or DC load. Electrodes 326 and 336 function as electrodes for DSSC 414.

In one embodiment of the present invention, the concentric tubes may be spaced from each other from about 0.1 μm to about 500 μm. The relative sizes of the inner and outer tube may be varied depending on the application. For example, the inner tube may be taller or shorter than the outer tube depending on the application.

In conventional solar cell architectures, solar cells are stacked on top of each other in a series where cathode of the first solar cell is in direct contact with the anode of the second solar cell. In this type of architecture the total open circuit voltage of the whole stack of cells is the sum of the open circuit voltage of the individual cells. Individual cells in tandem architectures can be chosen such that they absorb light from different regions of the solar spectrum so that complete absorption of incident light can be achieved. Since in dye sensitized solar cells there is a liquid electrolyte layer in between the cathode and the anode, a multilayer stacking of cells is not possible for DSSCs. Therefore, tandem architectures have been difficult to make. A parallel tandem structure has been made by sandwiching three flat substrates together to form multiple cells [6,7], but sealing the multiple cells on top of each other with electrolyte in between presents significant engineering challenges.

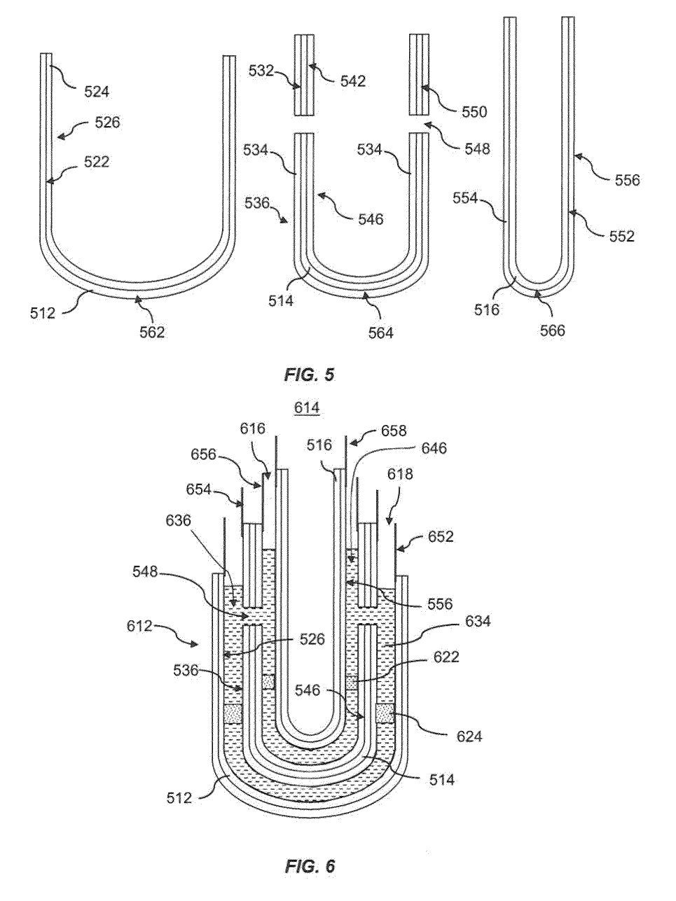

FIGS. 5 and 6 show how a multi-cell tandem structure may be made using the concentric tube technology of the present invention.

FIG. 5 shows an outer tube 512, a middle tube 514 and an inner tube 516. Inner tube 516 may be nested in middle tube 514 which is in turn nested in outer tube 512 to form a nested concentric tube module of the present invention as shown in FIG. 6. Outer tube 512 has coated on an inner side 522 coating layers 524 to form an outer electrode 526 comprising outer tube 512 and coating layers 524. Middle tube 514 has coated on an outer side 532 coating layers 534 to form an outer middle electrode 536 comprising middle tube 514 and outer coating layers 534. Middle tube 514 has coated on an inner side 542 an inner coating layers 544 to form an inner middle electrode 546 comprising middle tube 514 and coating layers 544. Middle tube 514 also has openings 548 in a cylindrical wall 550 of middle tube 514. Inner tube 516 has coated on an outer side 552 coating layers 554 to form an inner electrode 556 comprising inner tube 516 and coating layers 554. Outer tube 512 has a closed end 562. Middle tube has a closed end 564. Inner tube has a closed end 566.

FIG. 6 shows inner tube 516 mounted middle tube 514 which in turn is mounted in outer tube 512 to form a nested concentric tube module 612 that is part of a DSSC apparatus 614 that comprises two DSSCs, i.e., DSSCs 616 and 618. Inner tube 516 is spaced from middle tube 514 and held in place relative to middle tube 514 by a spacer 622. Middle tube 514 is spaced from outer tube 512 and held in place relative to outer tube 512 by a spacer 624. An electrolyte 634 partially fills a space 636 between outer tube 512 and middle tube 514. Electrolyte 634 also partially fills a space 646 between middle tube 514 and inner tube 516. Electrolyte 634 passes between space 636 and 646 via openings 548 that act as passageways between outer tube 512 and inner tube 516. Electrical leads 652 electrically connect outer electrode 526 to other circuitry (not shown) that lead to battery, power inverter or a DC load. Electrical leads 654 electrically connect outer middle electrode 536 to other circuitry (not shown) that lead to battery, power inverter or DC load. Electrical leads 656 electrically connect inner middle electrode 546 to other circuitry (not shown) that lead to battery, power inverter or DC load. Electrical leads 658 electrically connect inner electrode 556 to other circuitry (not shown) that lead to battery, power inverter or DC load. DSSC 616 comprises outer electrode 526, outer middle electrode 536 and space 636 filled with electrolyte 634 between outer tube 512 and middle tube 514. DSSC 618 comprises inner middle electrode 546, inner electrode 556 and space 646 filled with electrolyte 634 between middle tube 514 and inner tube 516.

In one embodiment of the present invention in which DSSC apparatus 614 has a multi-cell parallel tandem architecture, outer electrode 526 and inner electrode 556 may each be a photoanode and outer middle electrode 536 and inner middle electrode 546 may each be a photocathode. Outer electrode 526 is and inner electrode 556 are electrically connected through circuitry (not shown) and outer middle electrode 536 and inner middle electrode 546 are electrically connected to each other through circuitry (not shown).

In one embodiment of the present invention in which DSSC apparatus 614 has a multi-cell parallel tandem architecture, outer electrode 526 and inner electrode 556 may each be a photocathode and outer middle electrode 536 and inner middle electrode 546 may each be a photoanode. Outer electrode 526 is and inner electrode 556 are electrically connected through circuitry (not shown) and outer middle electrode 536 and inner middle electrode 546 are electrically connected to each other through circuitry (not shown).

In one embodiment of the present invention in which DSSC apparatus 614 has a multi-cell series tandem architecture, outer electrode 526 and inner middle electrode 546 may each be a photoanode and outer middle electrode 536 and inner electrode 556 may each be a photocathode. Outer electrode 526 is and inner middle electrode 546 are electrically connected through circuitry (not shown) and outer middle electrode 536 and inner electrode 556 are electrically connected to each other through circuitry (not shown).

In one embodiment of the present invention in which DSSC apparatus 614 has a multi-cell series tandem architecture, outer electrode 526 and inner middle electrode 546 may each be a photocathode and outer middle electrode 536 and inner electrode 556 may each be a photoanode. Outer electrode 526 is and inner middle electrode 546 are electrically connected through circuitry (not shown) and outer middle electrode 536 and inner electrode 556 are electrically connected to each other through circuitry (not shown).

Although only one middle tube is shown in the embodiment of the present invention shown in FIGS. 5 and 6, in other embodiments of the present invention there may be multiple middle tubes nested inside each other. Each middle tube in such a configuration is similar to the middle tube shown in FIGS. 5 and 6. For example, each middle tube in a multiple middle tube configuration includes has an outer coating layers on an outer side of the middle tube and an inner coating layers on the inner side of the inner tube that correspond to the outer coating layers and inner coating layers of the middle tube shown in FIGS. 5 and 6. Each middle tube also includes one or more openings that act as passageways between the outer tube a neighboring middle tube, the inner tube and a neighboring middle tube or between neighboring middle tubes.

In FIGS. 3, 4, 5 and 6, any of the electrodes may function as a photoanode, a photocathode or a cathode depending on the coating layers that are part of the electrode.

In one embodiment of the present invention, an electrode may be a photoanode. In one embodiment of the present invention, a photoanode comprises the following three coating layers on a side of the tube of the electrode: (1) a transparent conductor layer coated on the side of the tube, (2) a porous semiconductor layer on the transparent conductor layer and (3) an absorbing layer on the porous semiconductor layer. The porous semiconductor layer is comprised of one or more materials with pores having a diameter of about 2 nm to about 1 μm and that function as a n-type semiconductor. Suitable n-type semiconductors that may be used in the photoanodes of the present invention include TiO₂, ZnO, SnO₂, WO₃, Fe₂O₃ etc.

In one embodiment of the present invention in which the outer electrode functions as photoanode, the coating layers on the inner side of the outer tube include a layer of fluorinated tin oxide (FTO) that is coated directly on the inner tube. On top of the layer of FTO is a layer of mesoporous TiO₂. On top of the layer of mesoporous TiO₂ is a layer of dye molecules adsorbed on the surface of the TiO₂ particles. In this configuration, the outer electrode constitutes a photoanode. Although an example of the outer electrode functioning as a photoanode is described above, any of the electrodes may function as a photoanode depending on the application.

In one embodiment of the present invention, an electrode may function as a cathode. In one embodiment of the present invention, the cathode comprises the following two layers on a side of the tube of the electrode: (1) a transparent conductor layer on the side of the tube and (2) an interfacial conductor layer on the transparent conductor layer.

In one embodiment of the present invention in which the inner electrode functions as a cathode, the coating layers on the outer side of the inner electrode may include a layer of FTO that is coated directly on the outer tube. On top of the layer of FTO is a interfacial conductor layer of a conducting material that may comprise a single conducting material or a mixture of conducting materials such as solid platinum, platinum nanoparticles, a layer of carbon, carbon nanotubes (either single walled or multiwalled), PEDOT:PSS, a transparent conducting oxide, a semiconductor etc. Although an example of the inner electrode functioning as a cathode is described above, any of the electrodes may function as a cathode depending on the application.

In one embodiment of the present invention, an electrode may be a photocathode. In one embodiment of the present invention, a photocathode comprises the following three coating layers on a side of the tube of the electrode: (1) a transparent conductor layer coated on the side of the tube and (2) a porous semiconductor layer on the transparent conductor layer. The porous semiconductor layer is comprised of one or more p-type semiconductor materials with pores having a diameter of about 2 nm to about 1 μm and that function as a p-type semiconductor. Examples of suitable p-type semiconductors that may be used in photocathodes of the present invention include NiO, CuO, etc.

In one embodiment of the present invention, the inner electrode may be a photocathode. When the inner electrode is a photocathode, the inner electrode may have a layer of FTO that is coated directly on the inner tube. On top of the layer of FTO is a layer of a semiconductor, such as nickel oxide. A layer of dye molecules are adsorbed on the surface of the transparent semiconducting mesoporous oxide particles. A system comprising a photocathode is coupled with a photoanode through an electrolyte is referred to as a “series tandem architecture,” as described by Bach et al. [5]. Although an example of the inner electrode functioning as a photocathode is described above, any of the electrodes may function as a photoanode depending on the application.

In some embodiments of the present invention, there may be passageways in the apparatus to allow for the introduction of liquids and gases and for the removal of liquids or gases.

Although the tubes shown in FIGS. 3, 4, 5 and 6 have one closed end, in some embodiments of the present invention the tubes may have open ends. With open-ended tubes, a final seal may be made at both ends instead of at one end.

In one embodiment of a serial tandem architecture of the present invention, the outer electrode and the inner middle electrode each functions as photoanode, coating layers on the inner side of the outer tube and the inner side of the middle tube include a layer of fluorinated tin oxide (FTO) that is coated directly on the outer tube and middle tube, respectively. On top of the layer of FTO is a layer of mesoporous TiO₂. A layer of dye molecules adsorbed on the surface of the TiO₂ particles of the layer of layer of mesoporous TiO₂. In this configuration, the outer electrode constitutes a photoanode. In one embodiment of the present invention, the dye molecules used in the coating layers for the middle tube are different than the dye molecules used in the coating layers of the outer tube. In one embodiment of the present invention, the dye molecules used in the coating layers for the middle tube absorb one or more wavelengths of light that are different than the wavelengths of light absorbed by the dye molecules used in the coating layers for the outer tube. In one embodiment of the present invention, if there are two or more middle tubes, the dyes used in the coating layers for the middle tubes may absorb one or more wavelengths of light that are different than the wavelengths of light absorbed by the dye molecules used in the coating layers of the other middle tubes and the dye molecules used in the coating layers of the outer tube. By using dyes that absorb at different wavelength, a DSSC of the present invention is able to make use of a greater portion of the electromagnetic spectrum.

In some embodiments of the present invention two or more of the photoanodes may use the same dye.

In one embodiment of the present invention in which the inner electrode of FIG. 5 and FIG. 6 functions as a cathode, the coating layers on the outer side of the inner electrode may include a layer of FTO that is coated directly on the inner tube. On top of the layer of FTO is a interfacial conductor layer of a conducting material that may comprise a single conducting material or a mixture of conducting materials such as solid platinum, platinum nanoparticles, a layer of carbon, carbon nanotubes (either single walled or multiwalled), conducting polymer such as poly(3,4-ethylenedioxythiophene) poly(styrenesulfonate) (PEDOT:PSS), a transparent conducting oxide, a semiconductor etc.

In one embodiment of the present invention, the inner electrode of FIGS. 5 and 6 may be a photocathode. When the inner electrode is a photocathode, the inner electrode may have a layer of FTO that is coated directly on the inner tube. On top of the layer of FTO is a layer of a transparent semiconducting mesoporous oxide, such as nickel oxide. A layer of dye molecules are adsorbed on the surface of the transparent semiconducting mesoporous oxide particles. A system comprising a photocathode is coupled with a photoanode through an electrolyte is referred to as a “series tandem architecture,” as described by Bach et al. [5].

In the embodiment of the present invention shown in FIGS. 5 and 6, the DSSCs of the DSSC apparatus are connected by passageways that allow electrolyte to flow between the DSSCs. However, in other embodiments of the present invention, there may not be passageways between the adjacent DSSCs.

Suitable dyes that may be used in the photoanodes and photocathodes of the present invention may include various dyes including the dyes described in Gratzel [3], Hagfeldt et al. [4] and Bach et al. [5], the entire contents and disclosure of which is incorporated by reference.

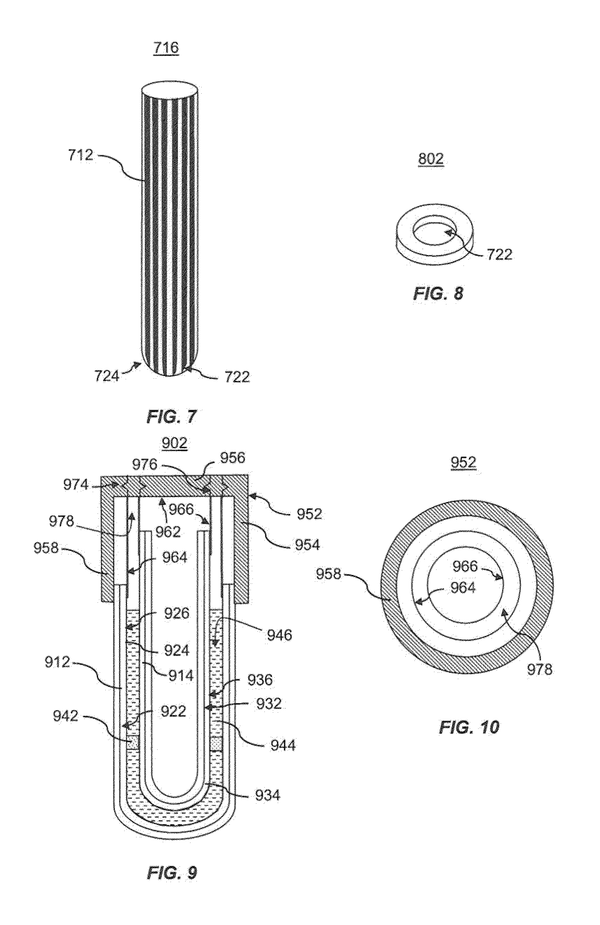

Although in some embodiments of the present invention, the coating layers may be deposited on the tubes as a continuous coating cover part or all of a side of a tube, in other embodiments of the present invention the coating layers or particular layers of the coating layers may be deposited in other patterns such as stripes, grids, etc. FIG. 7 shows an example of coating layers deposited as vertical segments 712 (dark) on an outer side 714 of a tube 716. Vertical segments 712 have tapered ends 722 at a bottom end 724 of tube 716.

Patterned coating layers or coating may be produced in various ways such as by scratching a pattern in the glass with a tool such as a caliper, a rotating or non-rotating blade, etc., by chemical etching, or by photolithographic methods.

Suitable spacers that may be used to space apart the tubes may take various shapes. FIG. 8 shows an example of an annular disc-shaped spacer 802 of the type used in FIGS. 4 and 6. Annular disc-shaped spacer 802 includes an opening 812 that allows spacer 802 to be fit on the end of a tube and slid down tube.

Although one shape of spacer is shown in FIG. 8, the spacers of the present invention may have virtually any suitable shape. Also, in place of a single spacer there may be multiple smaller spacers used around the circumference of the tube. Also, in FIGS. 4 and 6, spacers are only shown as being used at one point along the lengths of two neighboring tubes, there may be multiple spacers at different points along the lengths of neighboring tubes and at the bottom of the tubes. The spacers may act not only as mechanical supports but also to isolate the electrolyte in different segments. Alternately, the spacers may include openings or may be porous so that the electrolyte functions as a continuous electrolyte throughout the space between two neighboring tubes. Multiple spacers may also be arranged in patterns that leave openings that allow the electrolyte to functions as a continuous electrolyte throughout the space between two neighboring tubes.

In some embodiments of the present invention, the spacers may include interconnect that electrically connect the electrodes of adjacent cells. For example, the spacer may have conducting pathways on them that help connect a stripe one part of outer tube to a stripe on another part of the inner tube.

FIG. 9 shows a DSSC 902 an outer tube 912 in which an inner tube 914 is nested to form a nested concentric tube module 916 of the present invention. Outer tube 912 has coated on an inner side 922 coating layers 924 to form an outer electrode 926 comprising outer tube 912 and coating layers 924. Inner tube 914 has coated on an outer side 932 coating layers 934 to form an inner electrode 936 comprising inner tube 914 and coating layers 934. Inner tube 914 is spaced from outer tube 912 and held in place relative to outer tube 912 by a spacer 942. An electrolyte 944 partially fills a space 946 between outer tube 912 and inner tube 914. DSSC 902 includes a cap 952 comprising a cap body 954 having a top 956 and an outer cylindrical wall 958 that seals DSSC 902. Cap 952 is also shown in FIG. 10. Cap body 954 may be made of an insulating material such as glass, ceramic or plastic. Extending from an inner surface of 962 of cap body 954 are an outer cylindrical contact 964 and an inner cylindrical contact 966. Outer cylindrical contact 964 is in electrical contact with outer electrode 926. Inner cylindrical contact 966 is in electrical contact with inner electrode 936. Outer cylindrical contact 964 connects to circuitry 974 in cap body 954. Inner cylindrical contact 966 connects to circuitry 976 in cap body 956. Circuitry 974 and 976 in turn connect to additional circuitry or wires (not shown) that lead to a battery, other power inverter or DC load etc. Between outer cylindrical contact 964 and inner cylindrical contact 966 is a space 978.

Although shown only partially filling the space between the outer tube and inner tube in FIG. 9, the electrolyte may fill the entire space between the outer tube and the inner tube including into the space between the two cylindrical contacts.

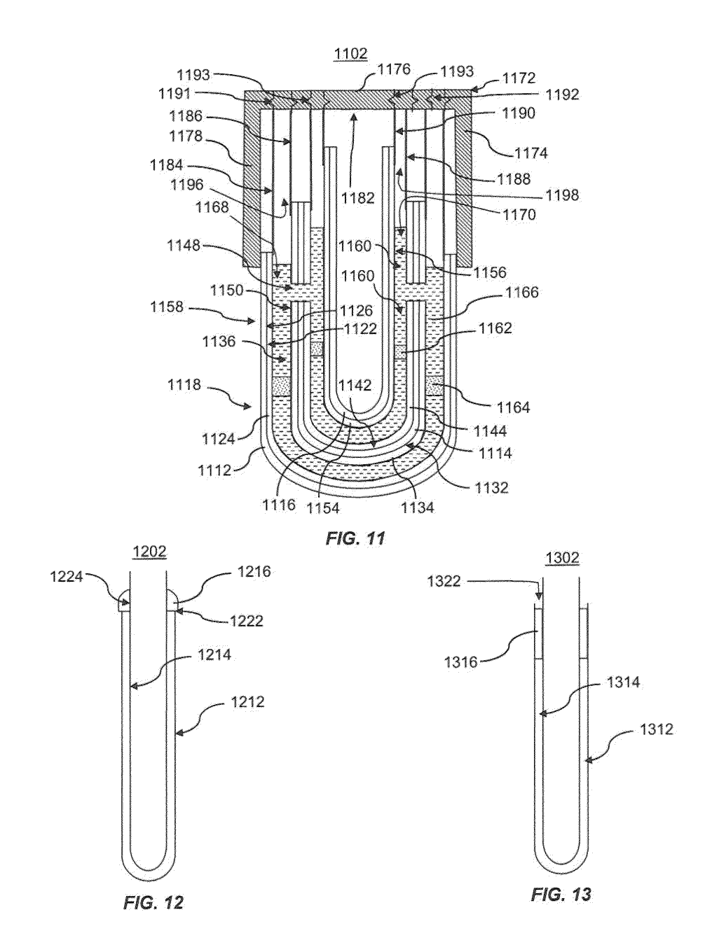

FIG. 11 shows a DSSC apparatus 1102 having an outer tube 1112, a middle tube 1114 and an inner tube 1116. Inner tube 1116 is nested in middle tube 1114 which is in turn nested in outer tube 1112 to form a nested concentric tube module of the present invention. Outer tube 1112 has coated on an inner side 1122 coating layers 1124 to form an outer electrode 1126 comprising outer tube 1112 and coating layers 1124. Middle tube 1114 has coated on an outer side 1132 coating layers 1134 to form an outer middle electrode 1136 comprising middle tube 1114 and coating layers 1134. Middle tube 1114 has coated on an inner side 1142 coating layers 1144 to form an inner middle electrode 1146 comprising middle tube 1114 and coating layers 1144. Middle tube 1114 also has openings 1148 in a cylindrical wall 1150 of middle tube 1114. Inner tube 1116 has coated on an outer side 1152 coating layers 1154 to form an inner electrode 1156 comprising inner tube 1116 and coating layers 1154.

DSSC apparatus 1102 comprises two DSSCs, i.e., DSSCs 1158 and 1160. Inner tube 1116 is spaced from middle tube 1114 and held in place relative to middle tube 1114 by a spacer 1162. Middle tube 1114 is spaced from outer tube 1112 and held in place relative to outer tube 1112 by a spacer 1164. An electrolyte 1166 partially fills a space 1168 between outer tube 1112 and middle tube 1114. Electrolyte 1166 also partially fills a space 1170 between middle tube 1114 and inner tube 1116. In addition, Electrolyte 1166 passes between space 1168 and 1170 via openings 1148 that act a passageways between outer tube 1112 and inner tube 1116. DSSC 1158 comprises outer electrode 1126, outer middle electrode 1136 and space 1168 filled with electrolyte 1166 between outer tube 1112 and middle tube 1114. DSSC 1160 comprises inner middle electrode 1146, inner electrode 1156 and space 1170 filled with electrolyte 1166 between middle tube 1114 and inner tube 1116.

DSSC apparatus 1102 includes a cap 1172 comprising a cap body 1174 having a top 1176 and an outer cylindrical wall 1178 that seal DSSC apparatus 1102. Cap body 1174 may be made of an insulating material such as glass, ceramic or plastic. Extending from an inner surface of 1182 of cap body 1174 are an outer cylindrical contact 1184, an outer middle cylindrical contact 1186, an inner middle cylindrical contact 1188 and an inner cylindrical contact 1190. Outer cylindrical contact 1184 is in electrical contact with outer electrode 1126. Outer middle cylindrical contact 1186 is in electrical contact with outer middle electrode 1136. Inner middle cylindrical contact 1188 is in electrical contact with inner middle electrode 1146. Inner cylindrical contact 1190 is in electrical contact with inner electrode 1156. Outer cylindrical contact 1184 connect to circuitry 1191 in cap body 1174. Outer middle cylindrical contact 1186 connect to circuitry 1192 in cap body 1174. Inner middle cylindrical contact 1188 connect to circuitry 1193 in cap body 1174. Inner cylindrical contact 1190 connects to circuitry 1194 in cap body 956. Circuitry 1191, 1192, 1193 and 1194 in turn connect to additional circuitry or wires (not shown) that lead to a battery, other power inverter, DC load, etc. or may be configured to ultimately lead to two electrode terminals, one positive and one negative, that may in turn lead to a battery, other power inverter, DC load, etc. Between outer cylindrical contact 1184 and outer middle cylindrical contact 1186 is a space 1196. Between inner middle cylindrical contact 1188 and inner cylindrical contact 1190 is a space 1198.

In one embodiment of the present invention in which DSSC apparatus 1102 has a multi-cell parallel tandem architecture, outer electrode 1126 and inner electrode 1156 may each be a photoanode and outer middle electrode 1136 and inner middle electrode 1146 may each be a photocathode. Outer electrode 1126 is and inner electrode 1156 are electrically connected through circuitry 1191 and 1194 and outer middle electrode 1136 and inner middle electrode 1146 are electrically connected to each other through circuitry 1192 and 1193.

In one embodiment of the present invention in which DSSC apparatus 1102 has a multi-cell parallel tandem architecture, outer electrode 1126 and inner electrode 1156 may each be a photoanode and outer middle electrode 1136 and inner middle electrode 1146 may each be a photocathode. Outer electrode 1126 is and inner electrode 1156 are electrically connected through circuitry 1191 and 1194 and outer middle electrode 1136 and inner middle electrode 1146 are electrically connected to each other through circuitry 1192 and 1193.

In one embodiment of the present invention in which DSSC apparatus 1102 has a multi-cell parallel tandem architecture, outer electrode 1126 and inner electrode 1156 may each be a photocathode and outer middle electrode 1136 and inner middle electrode 1146 may each be a photoanode. Outer electrode 1126 is and inner electrode 1156 are electrically connected through circuitry 1191 and 1194 and outer middle electrode 1136 and inner middle electrode 1146 are electrically connected to each other through circuitry 1192 and 1193.

In one embodiment of the present invention in which DSSC apparatus 1102 has a multi-cell series tandem architecture, outer electrode 1126 and inner middle electrode 1146 may each be a photoanode and outer middle electrode 1136 and inner electrode 1156 may each be a photocathode. Outer electrode 1126 is and inner middle electrode 1146 are electrically connected through circuitry 1191 and 1193 and outer middle electrode 1136 and inner electrode 1156 are electrically connected to each other through circuitry 1192 and 1194.

In one embodiment of the present invention in which DSSC apparatus 1102 has a multi-cell series tandem architecture, outer electrode 1126 and inner middle electrode 1146 may each be a photocathode and outer middle electrode 1136 and inner electrode 1156 may each be a photoanode. Outer electrode 1126 is and inner middle electrode 1146 are electrically connected through circuitry 1191 and 1193 and outer middle electrode 1136 and inner electrode 1156 are electrically connected to each other through circuitry 1192 and 1194.

Although only one middle tube is shown in FIG. 11, a cap of the type shown in FIG. 11 may also be used with a DSSC having multiple middle tubes by adding additional middle cylindrical contacts.

Although shown only partially filling the space between the outer tube and middle tube in FIG. 11, the electrolyte may fill the entire space between the outer tube and the middle tube including into the space between the outer and outer middle cylindrical contacts. Similarly, the electrolyte may fill the entire space between the middle tube and the inner tube including into the space between the inner middle and inner cylindrical contacts.

The nested concentric tube modules of the present have the advantage that the area sealing area is only the space between the tops of neighboring tubes as opposed to the flat modules of convention DSSCs that need to be sealed on all four sides. In addition to using a cap, as shown in FIGS. 9, 10 and 11 other ways of sealing the nested concentric tube modules of the present invention may be employed. Sealing the nested concentric tube modules prevents leakage of electrolyte and prevents the interior portions of the DSSC from being exposed to ambient conditions.

For example, FIG. 12 shows a nested concentric tube module 1202 having an outer tube 1212 and an inner tube 1214 that is sealed by a sealant 1216 located on top of a proximal edge 1222 of outer tube 1212 and against an outer side 1224 of inner tube 1214. FIG. 13 shows an alternative sealing method for a concentric tube module 1302 having an outer tube 1312 and an inner tube 1314. As shown in FIG. 13, a sealant 1316 is located in a gap 1322 between outer tube 1312 and inner tube 1314.

Suitable sealants for the tubes include epoxy glue, crosslinked polymers such as poly(dimethyl siloxane) (PDMS), Poly(methyl-silsesquioxane) (PMSSQ), Surlyn® sealant (an ionomer resin made by Dupont), spin-on glass, low melting glass, a ceramic, etc.

Photoelectrochemical cells have been proposed for use in H₂ production by water splitting for a long time. They have also been an active area of research for chemical fuels production (CH₄, methanol, ethanol, etc.) using light from the sun. DSSC are a special case of photoelectrochemical cell where the light from the sun is harvested to generate electricity. In terms of the design the major difference between a photoelectrochemical cell and a DSSC is that there has to be a ion exchange membrane in between the cathode and the anode to facilitate the passage of ions from anode to the cathode. In the concentric tube design, this feature can be achieved by inserting a free standing (flexible or rigid) polymer/ceramic ion exchange membrane. Also, the space between the outer tube and the inner tube may be much larger than for a DSSC.

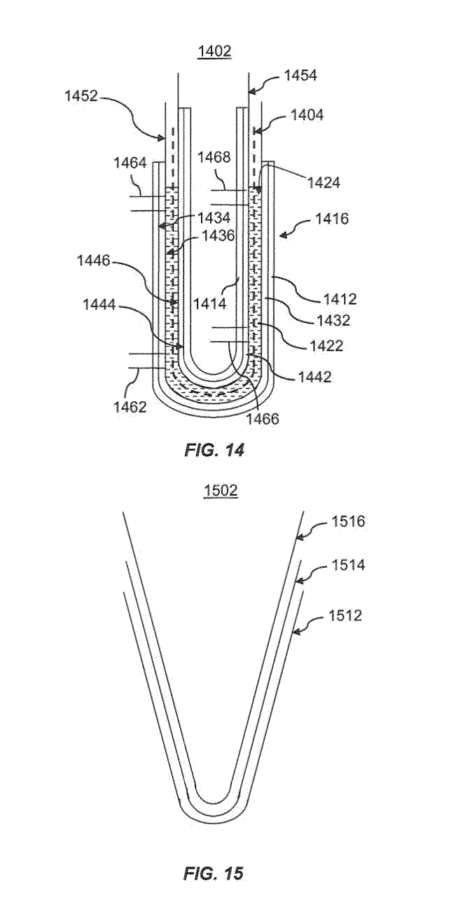

FIG. 14 shows a photoelectrochemical cell 1402 according to one embodiment of the present invention including an ion exchange membrane 1404 (dashed line) located between an outer tube 1412 and an inner tube 1414 of a nested concentric tube module 1416. Ion exchange membrane 1404 is suspended in an electrolyte 1422 in a space 1424 between outer tube 1412 and inner tube 1414. Outer tube 1412 has coating layers 1432 coated on an inner side 1434 of outer tube 1412 to form an outer electrode 1436 that functions as a photoanode. Inner tube 1414 has coating layers 1442 coated on an outer side 1444 of inner tube 1414 to form an inner electrode 1446 that functions as a photocathode. Electrical leads 1452 connect outer electrode 1436 to other circuitry (not shown) that connect outer electrode 1436 to a battery, DC power supply, power inverter or DC load etc. Electrical leads 1454 connect inner electrode 1446 to other circuitry (not shown) that connect outer electrode 1446 to a battery, DC power supply, power inverter or DC load etc. Outer tube 1412 has an inlet 1462 and an outlet 1464. Inner tube 1414 has an inlet 1466 and an outlet 1468. Inlet 1462 and inlet 1466 allows for reactants (not shown) to enter photoelectrochemical cell 1402. Outlet 1464 and an outlet 1468 allow products formed by photoelectrochemical reactions to be withdrawn from photoelectrochemical cell 1402.

Although FIG. 14 only shows an embodiment of the present invention having a photoelectrochemical cell with an outer tube and an inner tube, in other embodiments of the present invention, a photoelectrochemical cell may have one or more middle tubes that also form photoanodes and photocathodes.

In one embodiment of the present invention, a photoelectrochemical cell may have one or more middle tubes having outer coating layers to form photoanodes and outer coating layers to form photoanodes.

Although cylindrical tubes are shown and described above, the tubes of the present invention may have various shapes. For example, FIG. 15 shows a nested concentric tube module 1502 in which an outer tube 1512, a middle tube 1514 and an inner tube 1516 are tapered tubes. For simplicity of illustration, features such as coating layers, an electrolyte, etc. have been omitted from FIG. 15, but nested concentric tube module 1502 may be used in a DSSC, a photoelectrochemcial cell or other device in a fashion similar to the way that a nested concentric tube module comprised of cylindrical tubes may be used.

in some embodiments of the present invention, the tubes nested concentric tube module may not be straight cylinders but may be bent into various shapes as required. In such a case the tubes may be made of a rigid material such as glass or a more flexible material such as plastic. In one embodiment, the tubes of the present invention may be bent in helical shape such as a spring to provide a large surface area in a compact design.

In some embodiment, the tubes of the present invention may not have circular cross-sections such as in the cylindrical and tapered tubes described above and shown in the drawings. For example, the cross-sections of the tubes may be oval, lozenge-shaped, triangular, star-shaped, square-shaped, rectangular shaped, pentagon-shaped, hexagon-shaped, etc. or even irregular shaped. Such cross-sections may be combined with the tapered tube design to get a whole variety of shapes.

In one embodiment of the present invention, nested concentric hemispheres may be used in place of nested concentric tubes. All the other principles of design, device architecture, interconnects, fabrication, sealing, and process steps for making concentric nested hemisphere modules are similar to those used in making concentric nested tube modules. in this invention for a tubular design. As in the case of a nested concentric tube module, a stack of concentric hemispheres may also use the rings of various diameters to fit inside the hemisphere at particular locations thereby isolating the cells to the area between the adjacent rings in the hemispheres.

In one embodiment of the present invention, the nested concentric tube modules may be used in flexible solar cells (organic solar cells and others). Such sheets of flexible solar cells may be rolled and inserted in between concentric tubes that just function as passive encapsulation barriers and facilitate a tubular design. In this kind of design arrangement, it is important the solar cells have transparent/semitransparent electrodes. Also, when multiple sheets are used, the sheets may be connected as a parallel configuration and it would be advantageous to use a combination of sheets in which each one of them absorbs in a different area of the solar spectrum. It is also possible to make transparent organic solar cells with the tube as substrates and the concentric tubes connecting them in a parallel architecture.

Inside the hollow portion of a device of the present invention employing a nested concentric tube module, other kinds of energy harvesting and energy storage devices may be integrated. For example, solar cells can be assembled inside the hollow portion in a tubular geometry or as strips of flat solar cells can be joined in the form of a prism and inserted inside the cell. An electrochemical cell may be mounted inside the hollow portion and can use the power from the tubular cell to perform electrocatalytic processes. A battery can also be assembled inside along with an inverter (to convert DC to AC) so that each tube is an independent power unit. The space in the hollow portion can also be used to store gaseous fuel such as H₂ or CH₄.

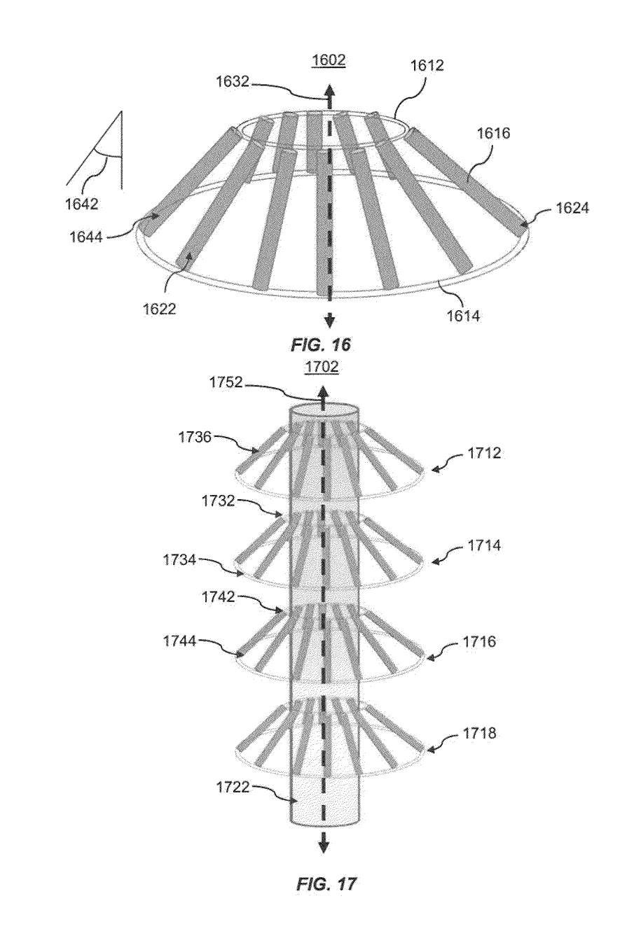

The nested concentric tube modules of the present invention may be mounted in a variety of ways. For example, FIG. 16 shows lampshade-shaped module 1602 according to one embodiment of the present invention comprising a smaller circular member 1612, a larger circular member 1614 and nested concentric tube modules 1616. A proximal end 1622 of each nested concentric tube module 1616 is attached to smaller circular member 1612 and a distal end 1624 is attached to larger circular member 1614 so that each nested concentric tube module 1616 is oriented in a radial direction and at angle with respect to an axis 1632 of lampshade-shaped module 1602. FIG. 16 shows an angle 1642 that a nested concentric tube module 1644 makes with axis 1632. Nested concentric tube module 1644 is one of nested concentric tube modules 1616.

The interconnection between each nested concentric module may be made in series and parallel using metallic conducting wires or strips to generate a certain voltage and current from the whole module assembly.

The nested concentric tube modules may be any type of nested concentric tube modules according to the present invention that can be mounted between the smaller and larger circular members.

FIG. 17 shows a solar tower 1702 in which four lampshade-shaped modules, i.e., lampshade-shaped modules 1712, 1714, 1716 and 1718 are mounted on a cylindrical post 1722. Cylindrical post 1722 extends through respective smaller circular members 1732 of lampshade-shaped modules 1712, 1714, 1716 and 1718. Each smaller circular member 1732 is attached to cylindrical post 1722. In addition to respective smaller circular members 1732, lampshade-shaped modules 1712, 1714, 1716 and 1718 each includes a larger circular member 1734 and nested concentric tube modules 1736. A proximal end 1742 of each nested concentric tube module 1736 is attached to smaller circular member 1732 and a distal end 1744 is attached to larger circular member 1734 so that each nested concentric tube module 1736 is oriented in a radial direction and at angle with respect to an axis 1752 for cylindrical post 1722 and for lampshade-shaped modules 1712, 1714, 1716 and 1718.

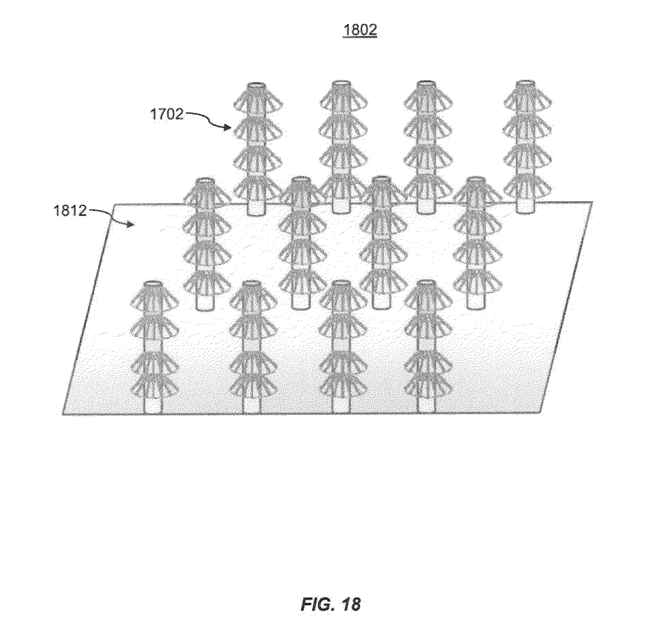

FIG. 18 shows an array 1802 of solar towers 1702 in a field 1812.

The “field” in which an array of solar towers are erected may be any type of region such as a field, a parking lot, a side of a hill, etc. Although shown as being flat in FIG. 18, the field may vary in topography. Also, the solar towers may be interspersed among other structures or buildings in the field. One or more of the solar towers may be used to provide electricity for standalone applications such as an electric vehicle charging station.

In FIGS. 17, 18 and 19, the lampshade-shaped modules may have nested concentric tube modules oriented at virtually any angle with respect to the axis of the lampshade-shaped modules from horizontal, to nearly vertical either up or down.

FIG. 19 shows a two-row rectangular module 1902 according to one embodiment of the present invention that comprises a vertical support member 1910, a vertical support member 1912, a horizontal support member 1914, a horizontal support member 1916 and a horizontal support member 1918. Horizontal support members 1914, 1916 and 1918 are mounted between and attached to vertical support members 1910 and 1912 to form a frame 1920. Mounted between horizontal support member 1914 and horizontal support member 1916 are nested concentric tube modules 1922 arranged in a row 1924. A proximal end 1926 of each nested concentric tube module 1922 is attached to horizontal support member 1914 and a distal end 1928 of each nested concentric tube module 1922 is attached to horizontal support member 1916. Mounted between horizontal support member 1916 and horizontal support member 1918 are nested concentric tube modules 1932 arranged in a row 1934. A proximal end 1936 of each nested concentric tube module 1932 is attached to horizontal support member 1916 and a distal end 1938 of each nested concentric tube module 1932 is attached to horizontal support member 1918.

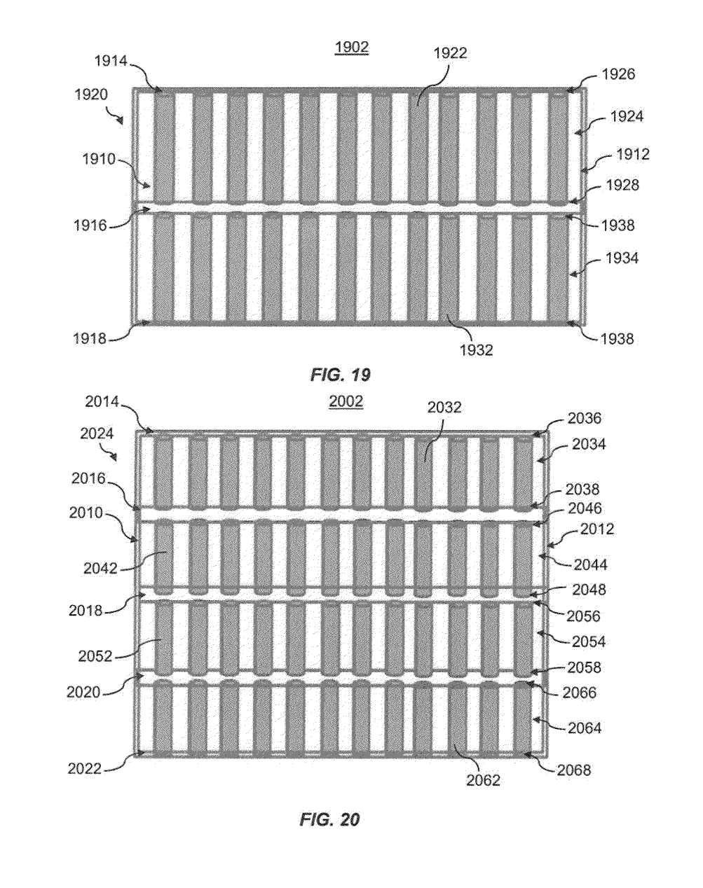

FIG. 20 show a four-row rectangular module 2002 according to one embodiment of the present invention that comprises a vertical support member 2010, a vertical support member 2012, a horizontal support member 2014, a horizontal support member 2016, a horizontal support member 2018, a horizontal support member 2020 and a horizontal support member 2022. Horizontal support members 2014, 2016, 2018, 2020 and 2022 are mounted between and attached to vertical support members 2010 and 2012 to form a frame 2024. Mounted between horizontal support member 2014 and horizontal support member 2016 are nested concentric tube modules 2032 arranged in a row 2034. A proximal end 2036 of each nested concentric tube module 2032 is attached to horizontal support member 2014 and a distal end 2038 of each nested concentric tube module 2032 is attached to horizontal support member 2016. Mounted between horizontal support member 2016 and horizontal support member 2018 are nested concentric tube modules 2042 arranged in a row 2044. A proximal end 2046 of each nested concentric tube module 2042 is attached to horizontal support member 2016 and a distal end 2048 of each nested concentric tube module 2032 is attached to horizontal support member 2018. Mounted between horizontal support member 2018 and horizontal support member 2020 are nested concentric tube modules 2052 arranged in a row 2054. A proximal end 2056 of each nested concentric tube module 2052 is attached to horizontal support member 2018 and a distal end 2058 of each nested concentric tube module 2052 is attached to horizontal support member 2020. Mounted between horizontal support member 2020 and horizontal support member 2022 are nested concentric tube modules 2062 arranged in a row 2064. A proximal end 2066 of each nested concentric tube module 2062 is attached to horizontal support member 2020 and a distal end 2068 of each nested concentric tube module 2062 is attached to horizontal support member 2022.

Although a particular number of nested concentric tube modules are shown in each row in FIGS. 19 and 20, various numbers of nested concentric tube modules may be in each row.

The nested concentric tube architecture of the present invention provides various advantages over conventional DSSC architectures. For example, in some embodiments, the present invention provides better efficiency. Compared to area of a flat surface, the surface area of a cylinder is 3.14 times higher for the diameter and length of tube equal to the width and length, respectively of flat surface. This means more light can be absorbed using a nested concentric tube architecture. Also, when using tubes have a circular cross-section, light incident from any direction is concentrated radially toward the center of the cross-section of the solar cell. This reduces reflection losses. Also, the orientation of a solar cell employing the nested concentric tube architecture of the present invention is more often optimal to absorb the light form any direction. So unlike solar cells on flat surface these need not be inclined at 45 degrees for optimal absorption. Even light reflected from different surfaces (direct or diffused) may also be harnessed.

DSSCs have already been shown to be invariant to the direct or diffused light and this would be a great factor in boosting the efficiency in our design of DSSCs. The parallel tandem design should in theory be able to at least double the currents in DSSCs and hence double the efficiency for a given dimension of the tube. In theory, the combined result of the two aspects mentioned above may increase the efficiency multiple times from what is achievable in single layer DSSCs on flat surfaces.

In some embodiments, the modular design of the nested concentric tube modules allows for ease of integration. Different tubes may be mass produced separately and assembled together to form the solar cells and modules. Also it is easier to handle tubes than big sheets of glass. This means size scaling of modules is much easier to do.

Another advantage of various embodiments of the present invention is that the tubes of nested concentric tube modules may handle liquid electrolytes in much better way. The sealing area is minimal, just the gap between neighboring tubes, so no useful area, which could have been used to absorb light, is lost. In contrast, in a flat design of DSSC modules, the integration of liquid electrolyte and sealing the module is a hard task and it becomes even more difficult if multiple cells have to be stacked on top of each other. Any solar cell lifetime issues arising out of electrolyte leaking because of poor sealing or the greater exposure of the interior in flat design DSS modules is also minimized in the nested concentric tube architecture of the present invention. Therefore, longer service lifetimes may be achieved by employing the nested concentric tube architecture of the present invention.

The nested concentric tube architecture of the present invention also allows for modifications future improvements in technology. For example, as the science and technology for harnessing near infrared and infrared parts of solar radiation is perfected, new concentric tubes may inserted without any design modification.

The nested concentric tube architecture of the present invention facilitates easier repair of the solar cells as the solar cells go bad over their lifetime. Most damage to DSSCs is caused by photo-bleaching of the dye, or the adverse effect of the electrolyte on the dye or the cathode over time. Sometimes, damage is caused by electrolyte degradation over time. In such situations the seal can be opened, the electrolyte may be drained out and filled with new one. The tubes can be cleaned in solvents that will remove the dye from photoanode. A fresh dye may then be adsorbed from solution. The FTO and mesoporous TiO₂ layers never require replacement.

Because the nested concentric tube architecture of the present invention is hollow from inside, this architecture provides a great deal of surface area for cooling in case a solar cell heats up. Also, other devices such as batteries etc. may be integrated in the hollow portion thus saving space and making it a compact multifunctional device. Photonic devices/structures/designs can be integrated in the hollow space or the surface of the hollow portion that can be used to channelize the light in the solar cell so as to maximize the absorption.

Processes for making the various parts of the device of the present invention will now be described. In this process, two steps are performed repeatedly to form a set of nested tubes of a nested concentric tube module: (1) coating and (2) annealing. Suitable coating processes that may be used in step 1 include dip coating, spray coating, atomic layer deposition, doctor blading, slot dyeing, sputtering and other solution and gas phase coating techniques, physical and chemical vapor deposition techniques, etc. Suitable annealing process that may be used in step 2 include furnace annealing, microwave annealing, laser annealing etc.

One method for forming a photoanode electrode from a tube of the present invention will now be described. A first layer comprising an FTO layer is coated on a side of the tube using a suitable coating method and annealed. A 2nd layer is of mesoporous TiO₂ which can be done using doctor blading a paste of TiO₂ nanoparticles and then annealing. Other methods may also be followed as reported in literature but adapted to a tubular design of the surface on which they are coated. The third “layer” in the coating layers is a dye adsorbed on the surface of the TiO₂ nanoparticles. The dye may be adsorbed on the TiO₂ nanoparticles by soaking a tube coated with the first two layers in a dye solution for a fixed number of hours. Depending on the type of dye, this time may typically vary from 4 to 24 hours.

One method of forming a cathode from a tube of the present invention will now be described. A first layer comprising FTO layer is coated on one side of the tube and then annealed to achieve a good quality transparent conductive oxide. The 2nd layer is the one that will be in contact with the electrolyte and take the hole from the electrolyte by a redox reaction. In one embodiment, the 2nd layer transparent or semitransparent. The use of a transparent or semitransparent 2nd layer is particular important if the cathode is formed from a middle tube, because a transparent or semitransparent layer will allow more light to pass through the walls of the middle tube. In such a case the 2nd layer may be a conducting polymer layer such as Poly (3,4-ethylene-dioxythiophene) poly(styrenesulfonate) (PEDOT:PSS) or a carbon nanotube layer (single walled or multiwalled) or other suitable transparent or semitransparent conductor or semiconductor. If PEDOT:PSS is used as the 2^{nd} layer, the tube may be dip coated or spray coated to achieve a thin film that can be annealed at 100 to 150° C. to form a good quality layer.

### REFERENCES

The following publications are referred to in the above-description of the present invention and are incorporated herein by reference:
1. A. Fujishima, K. Honda, ELECTROCHEMICAL PHOTOLYSIS OF WATER AT A SEMICONDUCTOR ELECTRODE. Nature 238, 37 (1972).
2. B. Oregan, M. Gratzel, A LOW-COST, HIGH-EFFICIENCY SOLAR-CELL BASED ON DYE-SENSITIZED COLLOIDAL TIO2 FILMS. Nature 353, 737 (Oct. 1991).
3. M. Gratzel, Dye-sensitized solar cells. Journal of Photochemistry and Photobiology C-Photochemistry Reviews 4, 145 (Oct. 2003).
4. A. Hagfeldt, G. Boschloo, L. C. Sun, L. Kloo, H. Pettersson, Dye-Sensitized Solar Cells. Chemical Reviews 110, 6595 (Nov. 2010).
5. A. Nattestad et al., Highly efficient photocathodes for dye-sensitized tandem solar cells. Nature Materials 9, 31 (Jan. 2010).
6. W. Kubo, A. Sakamoto, T. Kitamura, Y. Wada, S. Yanagida, Dye-sensitized solar cells: improvement of spectral response by tandem structure. Journal of Photochemistry and Photobiology α-Chemistry 164, 33 (Jun. 2004).
7. M. Durr, A. Bamedi, A. Yasuda, G. Nelles, Tandem dye-sensitized solar cell for improved power conversion efficiencies. Applied Physics Letters 84, 3397 (Apr. 2004).

Having described the many embodiments of the present invention in detail, it will be apparent that modifications and variations are possible without departing from the scope of the invention defined in the appended claims. Furthermore, it should be appreciated that all examples in the present disclosure, while illustrating many embodiments of the invention, are provided as non-limiting examples and are, therefore, not to be taken as limiting the various aspects so illustrated.

While the present invention has been disclosed with references to certain embodiments, numerous modification, alterations, and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

What is claimed is:

1. A device comprising one or more nested concentric tube modules, each nested concentric tube module comprising:
an outer tube having first coating layers coated on a inner side thereof, and
an inner tube having second coating layers coated on an outer side thereof,
wherein the inner tube is mounted inside the outer tube, is concentric with the outer tube and is spaced from the outer tube,
wherein the first coating layers comprise: a first transparent conductor layer, a porous semiconductor layer on the first transparent conductor layer and an absorbing layer on the porous semiconductor layer,
wherein the second coating layers comprise a second transparent conductor layer and an interfacial conductor layer on the second transparent conductor layer, and
wherein the porous semiconductor layer comprises one or more porous n-type semiconductor materials with pores having a diameter of about 2 nm to 1 μm.

2. The device of claim 1, wherein the device comprises an electrolyte at least partially filling a space between the outer tube and the inner tube.

3. The device of claim 2, wherein the device comprises an ion exchange membrane suspended in the electrolyte between the outer tube and the inner tube.

4. The device of claim 1, wherein the outer tube and the inner tube are tapered tubes.

5. The device of claim 1, wherein the device comprises a plurality of nested concentric tube modules.

6. A device comprising one or more nested concentric tube modules, each nested concentric tube module comprising:
an outer tube having first coating layers coated on a inner side thereof, and
an inner tube having second coating layers coated on an outer side thereof,
wherein the inner tube is mounted inside the outer tube, is concentric with the outer tube and is spaced from the outer tube,
wherein the first coating layers comprise a first transparent conductor layer and an interfacial conductor layer on the first transparent conductor layer,
wherein the second coating layers comprise: a second transparent conductor layer, a porous semiconductor layer on the second transparent conductor layer and an absorbing layer on the porous semiconductor layer, and
wherein the porous semiconductor layer comprises one or more porous n-type semiconductor materials with pores having a diameter of about 2 nm to 1 μm.

7. The device of claim 6, wherein the device comprises an electrolyte at least partially filling a space between the outer tube and the inner tube.

8. The device of claim 7, wherein the device comprises an ion exchange membrane suspended in the electrolyte between the outer tube and the inner tube.

9. The device of claim 6, wherein the outer tube and the inner tube are tapered tubes.

10. The device of claim 6, wherein the device comprises a plurality of nested concentric tube modules.

11. A device comprising one or more nested concentric tube modules, each nested concentric tube module comprising:
an outer tube having first coating layers coated on a inner side thereof, and
an inner tube having second coating layers coated on an outer side thereof,
wherein the inner tube is mounted inside the outer tube, is concentric with the outer tube and is spaced from the outer tube,
wherein the first coating layers comprise: a first transparent conductor layer, a first porous semiconductor layer on the first transparent conductor layer and a first absorbing layer on the first porous semiconductor layer,
wherein the second coating layers comprise: a second transparent conductor layer and a second porous semiconductor layer on the second transparent conductor layer,
wherein the first porous semiconductor layer comprises one or more porous n-type semiconductor materials with pores having a diameter of about 2 nm to 1 μm, and
wherein the second porous semiconductor layer comprises one or more porous p-type semiconductor materials with pores having a diameter of about 2 nm to 1 μm.

12. The device of claim 11, wherein the device comprises an electrolyte at least partially filling a space between the outer tube and the inner tube.

13. The device of claim 12, wherein the device comprises an ion exchange membrane suspended in the electrolyte between the outer tube and the inner tube.

14. The device of claim 11, wherein the outer tube and the inner tube are tapered tubes.

15. The device of claim 11, wherein the device comprises a plurality of nested concentric tube modules.

16. The device of claim 11, wherein the device comprises a middle tube having a third coating layer on an outer side thereof and a fourth coating layer on an inner side thereof,
wherein the outer tube, the inner tube, and the middle tube are concentric with each other,
wherein the outer tube is spaced from the middle tube,
wherein the inner tube is spaced from the middle tube,
wherein the third coating layers comprise: a third transparent conductor layer, a third porous semiconductor layer on the third transparent conductor layer and a second absorbing layer on the third porous semiconductor layer,
wherein the fourth coating layers comprise: a fourth transparent conductor layer and a fourth porous semiconductor layer on the fourth transparent conductor layer,
wherein the third porous semiconductor layer comprises one or more porous p-type semiconductor materials with pores having a diameter of about 2 nm to 1 μm, and
wherein the second porous semiconductor layer comprises one or more porous n-type semiconductor materials with pores having a diameter of about 2 nm to 1 μm.

17. The device of claim 16, wherein the device comprises an electrolyte at least partially filling a first space between the outer tube and a second space between the middle tube and between the middle tube and in the inner tube.

18. A device comprising one or more nested concentric tube modules, each nested concentric tube module comprising:
an outer tube having first coating layers coated on a inner side thereof, and
an inner tube having second coating layers coated on an outer side thereof,
wherein the inner tube is mounted inside the outer tube, is concentric with the outer tube and is spaced from the outer tube,
wherein the first coating layers comprise: a first transparent conductor layer and a first porous semiconductor layer on the first transparent conductor layer,
wherein the second coating layers comprise: a second transparent conductor layer, a second porous semiconductor layer on the second transparent conductor layer and a first absorbing layer on the first porous semiconductor layer,
wherein the first porous semiconductor layer comprises one or more porous p-type semiconductor materials with pores having a diameter of about 2 nm to 1 μm, and
wherein the second porous semiconductor layer comprises one or more porous n-type semiconductor materials with pores having a diameter of about 2 nm to 1 μm.

19. The device of claim 18, wherein the device comprises an electrolyte at least partially filling a space between the outer tube and the inner tube.

20. The device of claim 19, wherein the device comprises an ion exchange membrane suspended in the electrolyte between the outer tube and the inner tube.

21. The device of claim 18, wherein the outer tube and the inner tube are tapered tubes.

22. The device of claim 18, wherein the device comprises a plurality of nested concentric tube modules.

23. The device of claim 18, wherein the device comprises a middle tube having a third coating layer on an outer side thereof and a fourth coating layer on an inner side thereof,
wherein the outer tube, the inner tube, and the middle tube are concentric with each other,
wherein the outer tube is spaced from the middle tube,
wherein the inner tube is spaced from the middle tube,
wherein the third coating layers comprise: a third transparent conductor layer and a third porous semiconductor layer on the third transparent conductor layer,
wherein the fourth coating layers comprise: a fourth transparent conductor layer, a fourth porous semiconductor layer on the fourth transparent conductor layer and a second absorbing layer on the third porous semiconductor layer
wherein the third porous semiconductor layer comprises one or more porous n-type semiconductor materials with pores having a diameter of about 2 nm to 1 μm, and
wherein the second porous semiconductor layer comprises one or more porous p-type semiconductor materials with pores having a diameter of about 2 nm to 1 μm.

24. The device of claim 23, wherein the device comprises an electrolyte at least partially filling a first space between the outer tube and a second space between the middle tube and between the middle tube and in the inner tube.

25. A device comprising one or more nested concentric tube modules, each nested concentric tube module comprising:
an outer tube having first coating layers coated on a inner side thereof, and
an inner tube having second coating layers coated on an outer side thereof,
wherein the inner tube is mounted inside the outer tube, is concentric with the outer tube and is spaced from the outer tube,
wherein the first coating layers comprise: a first transparent conductor layer, a first porous semiconductor layer on the first transparent conductor layer and a first absorbing layer on the first porous semiconductor layer,
wherein the second coating layers comprise: a second transparent conductor layer, a second porous semiconductor layer on the second transparent conductor layer and a second absorbing layer on the second porous semiconductor layer,
wherein the first porous semiconductor layer comprises one or more porous n-type semiconductor materials with pores having a diameter of about 2 nm to 1 μm, and
wherein the second porous semiconductor layer comprises one or more porous n-type semiconductor materials with pores having a diameter of about 2 nm to 1 μm.

26. The device of claim 25, wherein the device comprises an electrolyte at least partially filling a space between the outer tube and the inner tube.

27. The device of claim 26, wherein the device comprises an ion exchange membrane suspended in the electrolyte between the outer tube and the inner tube.

28. The device of claim 25, wherein the outer tube and the inner tube are tapered tubes.

29. The device of claim 25, wherein the device comprises a plurality of nested concentric tube modules.

30. The device of claim 25, wherein the device comprises a middle tube having a third coating layer on an outer side thereof and a fourth coating layer on an inner side thereof,
wherein the outer tube, the inner tube, and the middle tube are concentric with each other,
wherein the outer tube is spaced from the middle tube,
wherein the inner tube is spaced from the middle tube,
wherein the third coating layers comprise: a third transparent conductor layer and a third porous semiconductor layer on the third transparent conductor layer,
wherein the fourth coating layers comprise: a fourth transparent conductor layer and a fourth porous semiconductor layer on the fourth transparent conductor layer,
wherein the third porous semiconductor layer comprises one or more porous p-type semiconductor materials with pores having a diameter of about 2 nm to 1 μm, and
wherein the second porous semiconductor layer comprises one or more porous p-type semiconductor materials with pores having a diameter of about 2 nm to 1 μm.

31. The device of claim 30, wherein the device comprises an electrolyte at least partially filling a first space between the outer tube and a second space between the middle tube and between the middle tube and in the inner tube.

32. A device comprising one or more nested concentric tube modules, each nested concentric tube module comprising:
an outer tube having first coating layers coated on a inner side thereof, and
an inner tube having second coating layers coated on an outer side thereof,
wherein the inner tube is mounted inside the outer tube, is concentric with the outer tube and is spaced from the outer tube,
wherein the first coating layers comprise: a first transparent conductor layer and a first porous semiconductor layer on the first transparent conductor layer,
wherein the second coating layers comprise: a second transparent conductor layer and a second porous semiconductor layer on the second transparent conductor layer,
wherein the first porous semiconductor layer comprises one or more porous p-type semiconductor materials with pores having a diameter of about 2 nm to 1 μm, and
wherein the second porous semiconductor layer comprises one or more porous p-type semiconductor materials with pores having a diameter of about 2 nm to 1 μm.

33. The device of claim 32, wherein the device comprises an electrolyte at least partially filling a space between the outer tube and the inner tube.

34. The device of claim 33, wherein the device comprises an ion exchange membrane suspended in the electrolyte between the outer tube and the inner tube.

35. The device of claim 32, wherein the outer tube and the inner tube are tapered tubes.

36. The device of claim 32, wherein the device comprises a plurality of nested concentric tube modules.

37. The device of claim 32, wherein the device comprises a middle tube having a third coating layer on an outer side thereof and a fourth coating layer on an inner side thereof,
wherein the outer tube, the inner tube, and the middle tube are concentric with each other,
wherein the outer tube is spaced from the middle tube,
wherein the inner tube is spaced from the middle tube,
wherein the third coating layers comprise: a third transparent conductor layer, a third porous semiconductor layer on the third transparent conductor layer and a first absorbing layer on the third porous semiconductor layer,
wherein the fourth coating layers comprise: a fourth transparent conductor layer, a fourth porous semiconductor layer on the fourth transparent conductor layer and a first absorbing layer on the first porous semiconductor layer,
wherein the third porous semiconductor layer comprises one or more porous n-type semiconductor materials with pores having a diameter of about 2 nm to 1 μm, and
wherein the second porous semiconductor layer comprises one or more porous n-type semiconductor materials with pores having a diameter of about 2 nm to 1 μm.

38. The device of claim 37, wherein the device comprises an electrolyte at least partially filling a first space between the outer tube and a second space between the middle tube and between the middle tube and in the inner tube.
